(19) United States
(12) Patent Application Publication
(10) Pub. No.: US 2026/0244458 A1
(43) Pub. Date: Aug. 20, 2026

(54) SUBSTRATE PROCESSING SYSTEM

(71) Applicant: EBARA CORPORATION, Tokyo (JP)

(72) Inventor: Kento YOSHIDA, Tokyo (JP)

(21) Appl. No.: 19/416,259

(22) Filed: Dec. 11, 2025

(30) Foreign Application Priority Data
Dec. 16, 2024 (JP) 2024-219702

(51) Int. Cl. G06F 9/448

(52) U.S. Cl. CPC G06F 9/4494

(57) ABSTRACT

A substrate processing system capable of reliably setting parameters without causing setting errors is disclosed. The substrate processing system comprises a communication network connected between a plurality of control devices and configured to transmit and receive parameters related to operating conditions of a device between the control devices.

### CROSS REFERENCE TO RELATED APPLICATION

This document claims priority to Japanese Patent Application No. 2024-219702 filed December 16, 2024, the entire contents of which are hereby incorporated by reference.

### BACKGROUND

A substrate processing apparatus that processes a substrate such as a wafer is known. In such a substrate processing apparatus, the wafer is transported to various modules and processed in each module. Each module includes various devices such as motors, sensors, and fluid control device.

In such various devices, it is necessary to set parameters for determining operating conditions of the devices according to the purpose of use. Generally, there is a method in which an operator operates buttons attached to individual devices to set the parameters.

However, in such a method, not only does it take a significant amount of time to set the parameters, but there is also a risk of causing setting errors (for example, erroneous input, forgetting to input, etc.). In this case, since the device does not operate normally, it is necessary to reset the parameters. As a result, there is a risk that downtime of the entire substrate processing apparatus may occur.

### SUMMARY

Therefore, there is provided a substrate processing system capable of reliably setting parameters without causing setting errors.

Embodiments, which will be described below, relate to a substrate processing system.

In an embodiment, there is provided a substrate processing system comprising a plurality of substrate processing apparatuses, each of the substrate processing apparatuses comprises: a control device; a device configured to operate a module or detect an operation of the module; and a fieldbus configured to electrically connect the control device and the device, and the substrate processing system comprises a communication network connected between a plurality of control devices including the control device and configured to transmit and receive parameters related to operating conditions of the device between the control devices.

In an embodiment, when a device serving as a setting reference for the parameter among a plurality of devices including the device is defined as a setting reference device, and a device subject to a setting change of the parameter is defined as a target device for change, the control device is configured to display at least one reference parameter corresponding to the setting reference device and at least one target parameter corresponding to the target device for change.

In an embodiment, the control device is configured to: compare the reference parameter and the target parameter; and reflect the selected reference parameter to the target parameter in a case in which the reference parameter and the target parameter do not match.

In an embodiment, the control device is configured to, after reflecting the selected reference parameter to the target parameter, confirm whether or not the target parameter matches the reference parameter.

In an embodiment, the substrate processing system is configured to: transmit and receive the parameter by Ethernet communication as the communication network; and transmit and receive the parameter by EtherCAT communication as the fieldbus.

In an embodiment, there is provided a substrate processing system comprising a substrate processing apparatus, the substrate processing apparatus comprises: a control device; a device configured to operate a module or detect an operation of the module; and a fieldbus configured to electrically connect the control device and the device, and the substrate processing system comprises: a data management device electrically connected to the control device; and a communication network configured to transmit and receive parameters related to operating conditions of the device between the control device and the data management device, and the data management device is configured to changeable manage the parameters stored therein.

In an embodiment, the data management device is configured to display a setting parameter for setting the operating condition of the device and a device parameter stored in the device.

In an embodiment, the data management device is configured to: compare the setting parameter and the device parameter; and cause the device parameter to match the setting parameter in a case in which the setting parameter and the device parameter do not match.

In an embodiment, the data management device is configured to, after causing the device parameter to match the setting parameter, confirm whether or not the device parameter matches the setting parameter.

In an embodiment, when replacing the device, the data management device is configured to transfer the parameter corresponding to the device to be replaced, which is stored therein, to a new device.

In an embodiment, comprising a plurality of substrate processing apparatuses including the substrate processing apparatus, and the data management device is configured to individually manage a plurality of parameters related to operating conditions of the devices included in each of the plurality of substrate processing apparatuses.

In an embodiment, the substrate processing system is configured to: transmit and receive the parameters by Ethernet communication as the communication network; and transmit and receive the parameters by EtherCAT communication as the fieldbus.

A substrate processing system comprising a communication network can transmit and receive parameters between a plurality of control devices. With such a configuration, an operator does not need to manually set parameters. As a result, the substrate processing system can reliably set parameters without causing setting errors.

A substrate processing system comprising a communication network can transmit and receive parameters between a control device and a data management device. With such a configuration, an operator does not need to manually set parameters. As a result, the substrate processing system can reliably set parameters without causing setting errors.

### BRIEF DESCRIPTION OF THE DRAWINGS

FIG. 1 is a diagram showing an embodiment of a substrate processing system;

FIG. 2 is a diagram showing an embodiment of a substrate processing apparatus;

FIG. 3 is a diagram showing an embodiment of a polishing module in a polishing section;

FIG. 4 is a diagram showing an embodiment of a cleaning module;

FIG. 5 is a diagram showing an embodiment of a temporary storage table;

FIG. 6 is a diagram showing an operation screen of a control device;

FIG. 7A is a diagram showing an operation flow of an operation screen when reflecting the reference parameter to the target parameter;

FIG. 7B is a diagram showing an operation flow of an operation screen when reflecting the reference parameter to the target parameter;

FIG. 7C is a diagram showing an operation flow of an operation screen when reflecting the reference parameter to the target parameter;

FIG. 7D is a diagram showing an operation flow of an operation screen when reflecting the reference parameter to the target parameter;

FIG. 7E is a diagram showing an operation flow of an operation screen when reflecting the reference parameter to the target parameter;

FIG. 7F is a diagram showing an operation flow of an operation screen when reflecting the reference parameter to the target parameter;

FIG. 8 is a diagram showing a processing flow of a control device when reflecting a reference parameter to a target parameter;

FIG. 9 is a diagram showing a processing flow of a control device when reflecting setting parameters to device parameters in one substrate processing apparatus;

FIG. 10 is a diagram showing a processing flow of a control device for managing firmware information;

FIG. 11 is a diagram showing another embodiment of a substrate processing system; and

FIG. 12 is a diagram showing another embodiment of a substrate processing system.

### DESCRIPTION OF EMBODIMENTS

Hereinafter, embodiments will be described with reference to the drawings. Note that, in the drawings described below, the same or corresponding constituent elements are denoted by the same reference numerals, and redundant description thereof is omitted. In a plurality of embodiments described below, the configuration of one embodiment not specifically described is the same as that of other embodiments, so that the redundant description thereof is omitted.

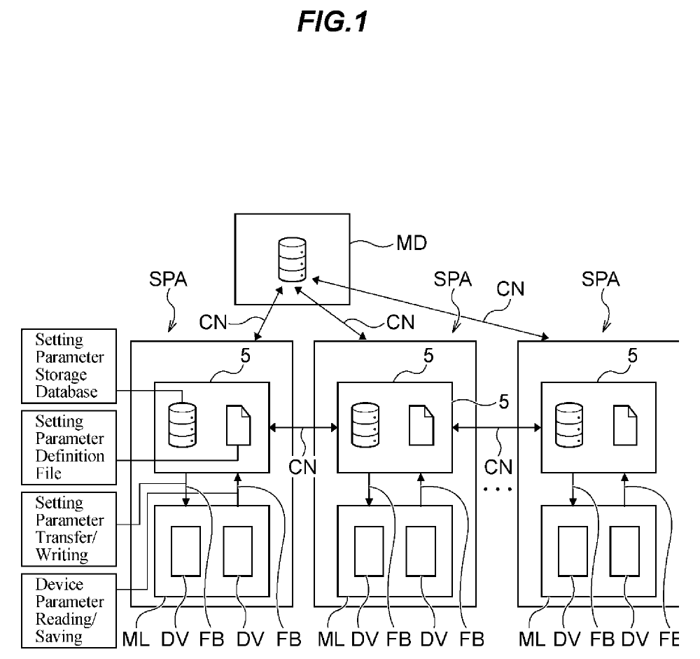

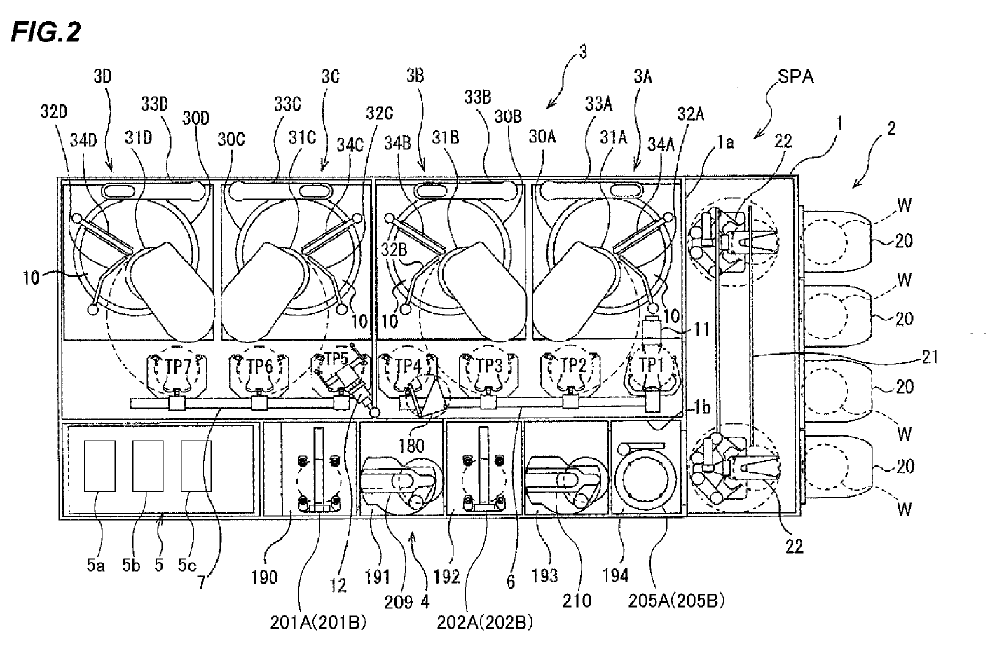

FIG. 1 is a diagram showing an embodiment of a substrate processing system. FIG. 2 is a diagram showing an embodiment of a substrate processing apparatus. As shown in FIG. 1, the substrate processing system comprises a plurality of substrate processing apparatuses SPA. As an example, the substrate processing apparatus SPA is a polishing apparatus for polishing a substrate.

As shown in FIG. 2, the substrate processing apparatus SPA comprises a substantially rectangular housing 1. The interior of the housing 1 is partitioned into a load/unload section 2, a polishing section 3, and a cleaning section 4 by partition walls 1a and 1b.

The substrate processing apparatus SPA comprises a control device 5 that controls a substrate processing operation. The control device 5 comprises a storage device 5a storing a program and a processing device 5b executing calculations according to the program. The control device 5 composed of a computer operates according to a program electrically stored in the storage device 5a.

The load/unload section 2 comprises two or more (four in the present embodiment) front load sections 20 on which wafer cassettes for stocking a large number of wafers W (substrates) are placed. A traveling mechanism 21 is laid in the load/unload section 2 along the arrangement direction of the front load sections 20, and two transport robots (loaders) 22 movable along the arrangement direction of the wafer cassettes are installed on the traveling mechanism 21.

The polishing section 3 is an area where polishing (planarization) of the wafer W is performed, and comprises a first polishing module 3A, a second polishing module 3B, a third polishing module 3C, and a fourth polishing module 3D.

As shown in FIG. 2, the first polishing module 3A comprises a polishing table 30A to which a polishing pad 10 having a polishing surface is attached, a top ring 31A for holding the wafer W and polishing the wafer W while pressing it against the polishing pad 10 on the polishing table 30A, a polishing liquid supply nozzle 32A for supplying a polishing liquid or dressing liquid (e.g., pure water) to the polishing pad 10, a dresser 33A for dressing the polishing surface of the polishing pad 10, and an atomizer 34A for spraying a mixed fluid of a liquid (e.g., pure water) and a gas (e.g., nitrogen gas) or a liquid (e.g., pure water) in the form of a mist onto the polishing surface. The second to fourth polishing modules 3B to 3D have the same constituent elements as the first polishing module 3A.

A transport mechanism for transporting the wafer W will be described. As shown in FIG. 2, the substrate processing apparatus SPA comprises a first linear transporter 6 disposed adjacent to the first polishing module 3A and the second polishing module 3B. The first linear transporter 6 is a mechanism for transporting the wafer W between four transport positions (a first transport position TP1, a second transport position TP2, a third transport position TP3, and a fourth transport position TP4) along an arrangement direction of the polishing modules 3A and 3B.

The substrate processing apparatus SPA comprises a second linear transporter 7 disposed adjacent to the third polishing module 3C and the fourth polishing module 3D. The second linear transporter 7 is a mechanism for transporting the wafer W between three transport positions (a fifth transport position TP5, a sixth transport position TP6, and a seventh transport position TP7) along an arrangement direction of the polishing modules 3C and 3D.

A lifter 11 for receiving a wafer W from the transport robot 22 is disposed at the first transport position TP1. The wafer W is transferred from the transport robot 22 to the first linear transporter 6 via the lifter 11.

A swing transporter 12 is disposed between the first linear transporter 6, the second linear transporter 7, and the cleaning section 4. The swing transporter 12 has a hand movable between the fourth transport position TP4 and the fifth transport position TP5. Transfer of the wafer W from the first linear transporter 6 to the second linear transporter 7 is performed by the swing transporter 12.

The wafer W polished in the polishing section 3 is transported by the swing transporter 12 to the cleaning section 4 via a temporary storage table. The cleaning section 4 is partitioned into a first cleaning chamber 190, a first transport chamber 191, a second cleaning chamber 192, a second transport chamber 193, and a drying chamber 194. In the first cleaning chamber 190, an upper primary cleaning module 201A and a lower primary cleaning module 201B arranged along the longitudinal direction are disposed.

The upper primary cleaning module 201A is disposed above the lower primary cleaning module 201B. Similarly, in the second cleaning chamber 192, an upper secondary cleaning module 202A and a lower secondary cleaning module 202B arranged along the longitudinal direction are disposed.

In the drying chamber 194, an upper drying module 205A and a lower drying module 205B arranged along the longitudinal direction are disposed. A first transport robot 209 capable of moving up and down is disposed in the first transport chamber 191, and a second transport robot 210 capable of moving up and down is disposed in the second transport chamber 193. The first transport robot 209 and the second transport robot 210 are movable up and down.

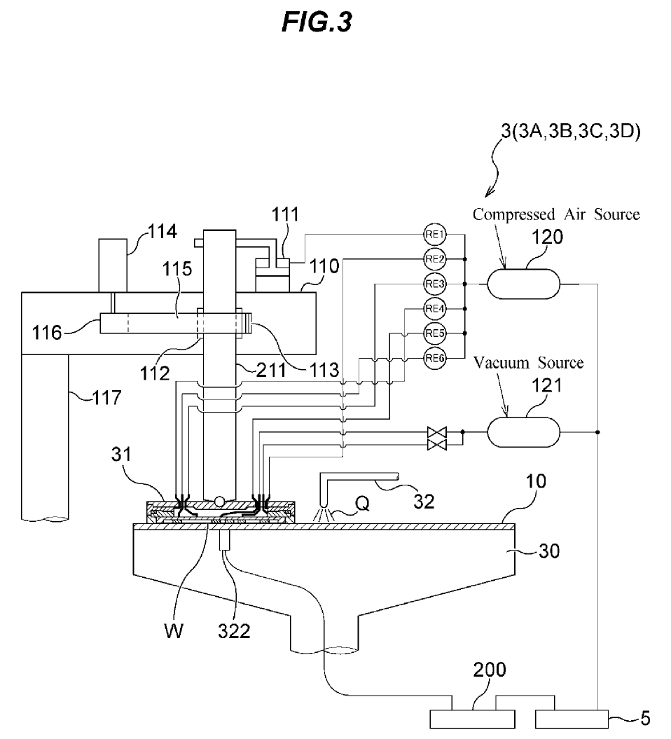

FIG. 3 is a diagram showing an embodiment of a polishing module in a polishing section. Hereinafter, the first polishing module 3A, the second polishing module 3B, the third polishing module 3C, and the fourth polishing module 3D may be collectively referred to as a polishing module 3.

As shown in FIG. 3, the polishing table 30 is disposed below the top ring 31, and the polishing liquid supply nozzle 32 is disposed above the polishing pad 10 attached to the upper surface of the polishing table 30.

The top ring 31 is connected to a top ring drive shaft 211. The top ring drive shaft 211 is coupled (indirectly connected) to a top ring air cylinder 111 fixed to a top ring head 110.

The top ring air cylinder 111 moves the top ring drive shaft 211 up and down to raise and lower the entire top ring 31. The top ring air cylinder 111 is configured to press the top ring 31 against the polishing table 30 by lowering the top ring 31.

The top ring air cylinder 111 is connected to a compressed air source 120 via a regulator RE1. The regulator RE1 is configured to adjust the pressure of compressed air supplied to the top ring air cylinder 111.

The top ring drive shaft 211 is coupled to a rotating cylinder 112 via a key (not shown). The rotating cylinder 112 comprises a timing pulley 113 formed on an outer peripheral portion thereof. A top ring motor 114 is fixed to the top ring head 110. The timing pulley 113 is connected to a timing pulley 116 connected to the top ring motor 114 via a timing belt 115.

The top ring 31 has a plurality of pressure chambers (not shown). These plurality of pressure chambers are connected to the compressed air source 120 via regulators RE2 to RE6. Accordingly, the regulators RE2 to RE6 are configured to adjust the pressure of compressed air supplied to each of the plurality of pressure chambers of the top ring 31.

Some of the plurality of pressure chambers are connected to a vacuum source 121. Accordingly, when the vacuum source 121 is driven, a vacuum is formed in the pressure chamber connected to the vacuum source 121. A communication hole is formed in the lower surface of this pressure chamber. Accordingly, a wafer W contacting the lower surface of the pressure chamber is suctioned by the top ring 31.

During polishing of the wafer W, in a state where suction of the wafer W is released, the top ring 31 holds the wafer W on its lower surface, and the control device 5 operates the top ring air cylinder 111. Further, the control device 5 supplies compressed air to the pressure chamber by operating the compressed air source 120, thereby pressing the wafer W against the polishing pad 10. By supplying a polishing liquid Q onto the polishing pad 10 from the polishing liquid supply nozzle 32, the wafer W is polished in a state where the polishing liquid Q exists between the surface to be polished of the wafer W and the polishing pad 10.

The polishing module 3 comprises an eddy current sensor 322 disposed inside the polishing table 30 and for detecting the thickness of a wafer W, and a thickness measuring device 200 connected to the eddy current sensor 322 and for measuring the thickness of the wafer W. The thickness measuring device 200 is electrically connected to the control device 5, and the control device 5 is configured to acquire the thickness of the wafer W measured by the thickness measuring device 200.

When the eddy current sensor 322 detects the thickness of the wafer W, the thickness measuring device 200 measures the thickness of the wafer W. The control device 5 controls polishing of the wafer W based on the thickness of the wafer W measured by the thickness measuring device 200. When the thickness of the wafer W reaches a predetermined thickness, the control device 5 ends the polishing of the wafer W.

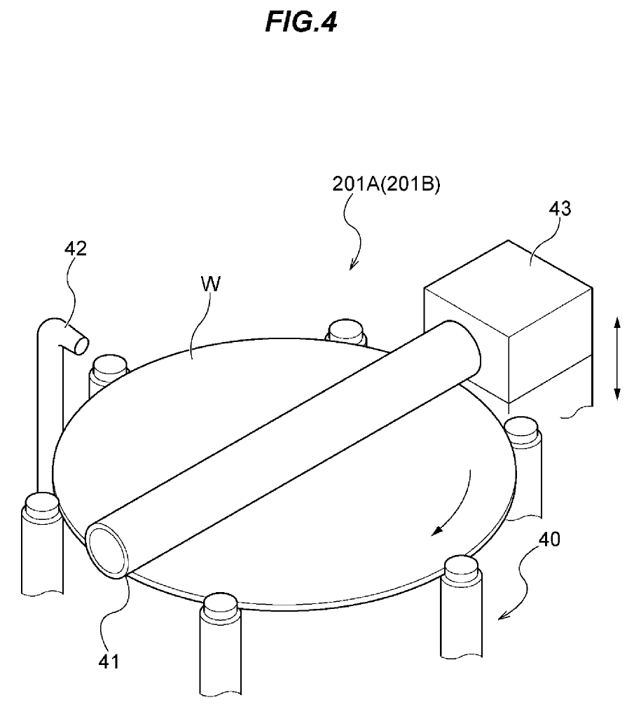

FIG. 4 is a diagram showing an embodiment of a cleaning module. In the embodiment shown in FIG. 4, the configuration of the cleaning module 201A (and cleaning module 202A) will be described. In one embodiment, the cleaning module 201B (and cleaning module 202B) may have the same configuration as the cleaning module 201A (and cleaning module 202A). Hereinafter, the cleaning module 201A and the cleaning module 202A may be collectively referred to as a cleaning module 201.

As shown in FIG. 4, the cleaning module 201 comprises a spin chuck 40 for rotating a wafer W while holding the polished wafer W, a roll sponge 41 rotating around an axis parallel to the surface of the wafer W, a cleaning liquid nozzle 42 for supplying a cleaning liquid to a surface to be cleaned of the wafer W, and a support drive device 43 for rotating the roll sponge 41.

When the control device 5 operates the support drive device 43, the roll sponge 41 rotates and is configured to clean the surface of the wafer W while rubbing it. Further, when the control device 5 operates the spin chuck 40, the spin chuck 40 rotates while supporting the outer peripheral surface of the wafer W and is configured to rotate the wafer W.

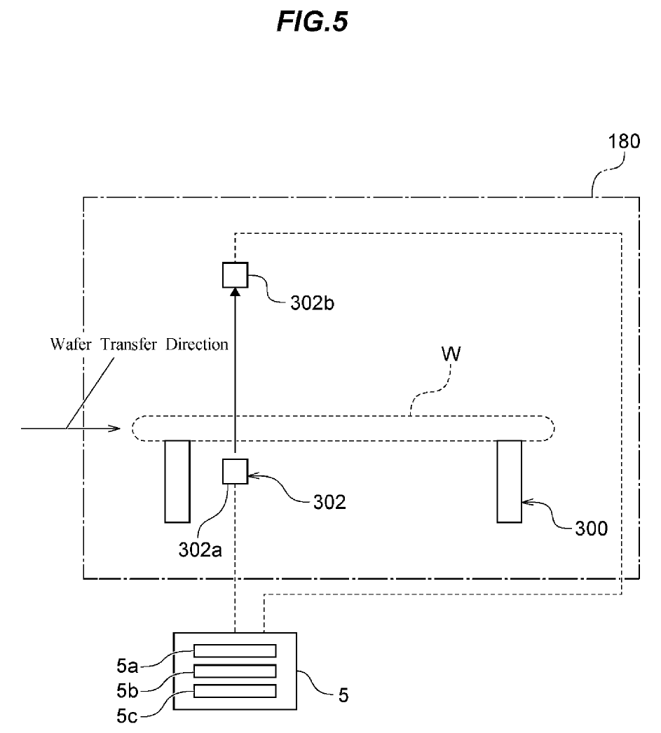

FIG. 5 is a diagram showing an embodiment of a temporary storage table. The substrate processing apparatus SPA comprises an optical sensor 302 for detecting presence or absence of the wafer W transported to a temporary storage table 180, and a mounting stage 300 for mounting the wafer W.

The optical sensor 302 comprises a light projecting part 302a emitting light and a light receiving part 302b receiving the light emitted from the light projecting part 302a. The optical sensor 302 is electrically connected to the control device 5. The control device 5 is configured to control the light projecting operation (that is, the start and stop of light irradiation) of the optical sensor 302 (more specifically, the light projecting part 302a).

When the light receiving part 302b receives the light emitted from the light projecting part 302a, the light receiving part 302b is configured to send a detection signal to the control device 5. When the control device 5 receives the detection signal from the light receiving part 302b, the control device 5 determines that the wafer W is not present on the mounting stage 300. The control device 5 determines that the wafer W is mounted on the mounting stage 300 based on the stop of transmission of the detection signal.

Returning to FIG. 1, the substrate processing system comprises a communication network CN for electrically connecting a plurality of substrate processing apparatuses SPA, and a data management device MD electrically connected to each of the plurality of substrate processing apparatuses SPA. The data management device MD is connected to the substrate processing apparatus SPA by a communication network CN different from the communication network CN connecting the plurality of substrate processing apparatuses SPA.

Hereinafter, in this specification, the polishing module 3, the cleaning module 201, and the drying module 205 may be collectively referred to as a module ML. The module ML is configured to process the wafer W and comprises a device DV necessary for processing the wafer W.

The device DV is configured to operate the module ML or detect an operation of the module ML. As an example of the device DV, actuators such as motors (more specifically, drivers, amplifiers, etc.) and sensors (for example, pressure sensors, flow rate sensors, optical sensors, etc.) can be given. An example of the device DV in the substrate processing apparatus SPA is as follows.

The polishing module 3 comprises, as examples of the device DV, the top ring motor 114, the regulators RE1 to RE6, a motor (not shown) for rotating the polishing table 30, the eddy current sensor 322, and the like.

The cleaning module 201 comprises, as examples of the device DV, a motor (not shown) for operating the spin chuck 40, the support drive device 43, and the like. The device DV may be the optical sensor 302 disposed at the temporary storage table 180 or various sensors (for example, a pressure sensor, a temperature sensor, a flow rate sensor, etc.) disposed at each module ML.

The communication network CN is configured to transmit and receive data between a plurality of substrate processing apparatuses SPA. The communication network CN is, for example, Ethernet (registered trademark) communication, wired communication, or wireless communication (for example, Wi-Fi (registered trademark) or Bluetooth (registered trademark)).

Data transmitted and received includes, in particular, parameters related to operating conditions of the device DV. The parameters correspond to, for example, set values for operating the device DV so as to adapt to the usage environment of the substrate processing apparatus SPA.

For example, when the device DV is a motor, the parameters correspond to gain settings for adjusting response performance and control accuracy of the motor, conditions determining the rotation direction of the motor, and the like. For example, when the device DV is a sensor, the parameters correspond to set values determining detection conditions of the sensor, threshold values for issuing alarms, and the like.

As shown in FIG. 1, the substrate processing apparatus SPA comprises a fieldbus (that is, a field network) FB for electrically connecting the control device 5 and the device DV. The control device 5 comprises a communication controller 5c enabling transmission and reception of data with the device DV through the fieldbus FB (see FIG. 2).

The fieldbus FB connects the communication controller 5c of the control device 5 and the device DV such as an actuator or a sensor, and is configured to enable transmission and reception of data (particularly, parameters). As examples of the fieldbus FB, EtherCAT (registered trademark) communication having high real-time performance and IO-Link (registered trademark) communication can be mentioned.

As described above, it is necessary to set parameters in the device DV according to the purpose of use of the device DV. However, if an operator manually sets parameters, it takes a long time and further, there is a risk of causing setting errors. Therefore, the substrate processing system can reliably set parameters without causing setting errors. Hereinafter, the detailed configuration of the substrate processing system will be described.

The substrate processing system is configured to transmit and receive parameters between a plurality of control devices 5 mounted on a plurality of substrate processing apparatuses SPA through the communication network CN. More specifically, the control device 5 can not only read parameters of the substrate processing apparatus SPA to which it itself belongs, but can also read parameters of other substrate processing apparatuses SPA connected by the communication network CN. Further, the control device 5 can rewrite parameters of other substrate processing apparatuses SPA.

As shown in FIG. 1, the control device 5 stores a setting parameter storage database and/or a setting parameter definition file therein, and is configured to transmit and receive the setting parameter storage database and/or the setting parameter definition file through the communication network CN.

The setting parameter is a parameter for setting an operating condition of the device DV. The setting parameter storage database is a database for centrally managing setting parameters, and stores not only current setting parameters but also a history (data) of past setting parameters. Therefore, an operator can confirm not only current setting parameters but also past setting parameters by accessing the setting parameter storage database.

The setting parameter definition file is a file summarizing documented setting parameters. By executing the conversion of setting parameters into a definition file, the control device 5 can document the setting parameters. The documented setting parameters can be transmitted and received offline between a plurality of control devices 5 through the communication network CN.

The control device 5 and the device DV are electrically connected by the fieldbus FB. Accordingly, the control device 5 transfers (writes) the setting parameters stored therein to the device DV through the fieldbus FB. By transferring the setting parameters to the device DV, the device DV stores the setting parameters.

The parameters stored in the device DV are called device parameters. The control device 5 reads device parameters from the device DV through the fieldbus FB. The control device 5 can store the device parameters read from the device DV.

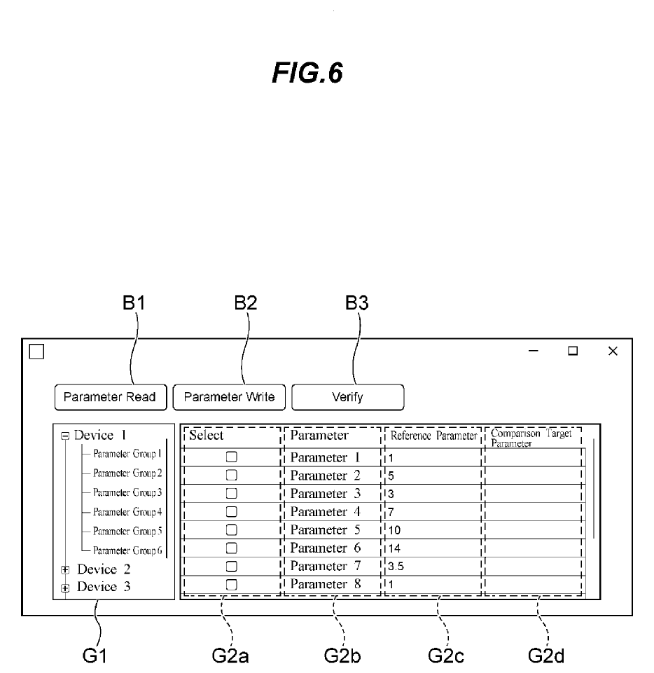

FIG. 6 is a diagram showing an operation screen of a control device. Each of the plurality of control devices 5 has a monitor (not shown) for displaying the operation screen shown in FIG. 6, and the operation screen is displayed on this monitor.

The operation screen has a read button B1 for reading parameters. When an operator selects the read button B1 (for example, clicks with a mouse), data (history) stored in the setting parameter storage database and/or device parameters stored in the device DV are read.

The operation screen has a list image G1 displaying a list of devices DV connected to the module ML and parameter groups related to each device DV. The operator can grasp the list of devices DV and the parameter groups at a glance through the list image G1. The parameter group means a group of classified parameters such as, for example, condition parameters, calibration parameters, and the like.

Further, the operation screen has a selection image G2a for selecting parameters to be transferred, and a parameter name display image G2b for displaying the name of each parameter belonging to the parameter group. The selectable parameters displayed in the selection image G2a and the parameters displayed in the parameter name display image G2b correspond to each other.

Hereinafter, in this specification, a device DV that serves as a setting reference for parameters among a plurality of devices DV is defined as a reference device (setting reference device), and a device DV (excluding the reference device) that is a target of parameter setting changes is defined as a target device (target device for change).

The operation screen has a reference parameter display image G2c for displaying a reference parameter corresponding to the reference device, and a target parameter display image G2d for displaying a comparison target parameter (target parameter) corresponding to the target device.

The reference parameter display image G2c and the target parameter display image G2d are arranged adjacent to each other, and numerical values of each parameter have a correspondence relationship. Therefore, the operator can grasp at a glance matching parameters and mismatched parameters.

When the operator selects the read button B1 (for example, clicks with a mouse), the control device 5 displays numerical values of setting parameters of the reference device stored therein, or numerical values of device parameters read from the reference device, on the reference parameter display image G2c.

When the operator selects the read button B1, the control device 5 displays the target parameter of the target device in the target parameter display image G2d. More specifically, the control device 5 displays numerical values of setting parameters of the target device stored therein, or numerical values of device parameters read from the target device, on the target parameter display image G2d.

In the embodiment shown in FIG. 6, the control device 5 displays a plurality of (eight in the present embodiment) reference parameters and a plurality of (eight in the present embodiment) target parameters, but the control device 5 does not necessarily need to display a plurality of reference parameters and target parameters. The control device 5 may display at least one reference parameter and at least one target parameter.

As shown in FIG. 6, the operation screen has a compare button B3 for comparing the reference parameter and the target parameter. When an operator selects the compare button B3, the control device 5 compares the reference parameter displayed in the reference parameter display image G2c and the target parameter displayed in the target parameter display image G2d.

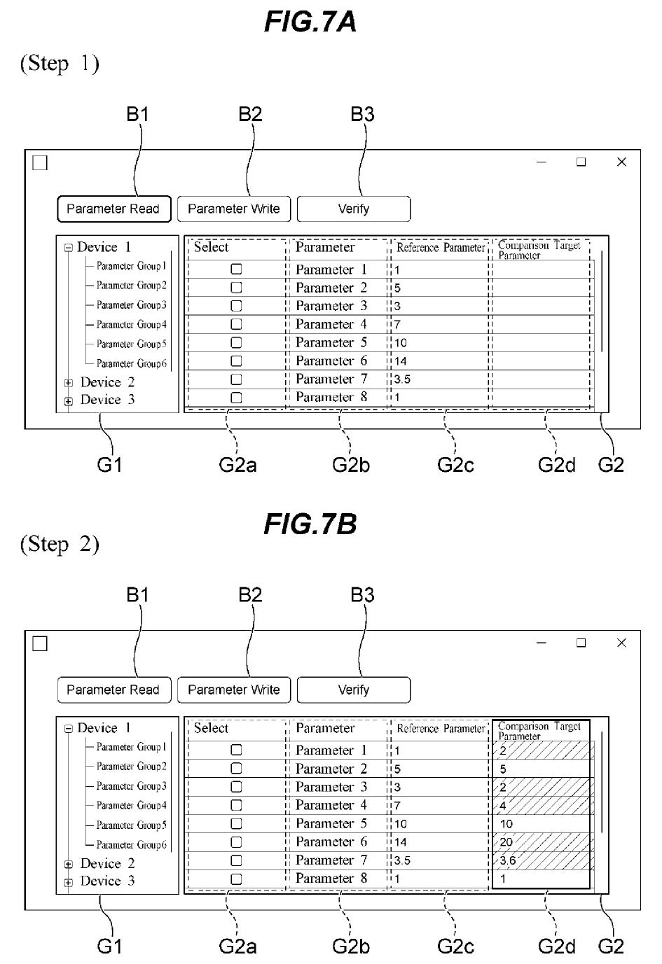

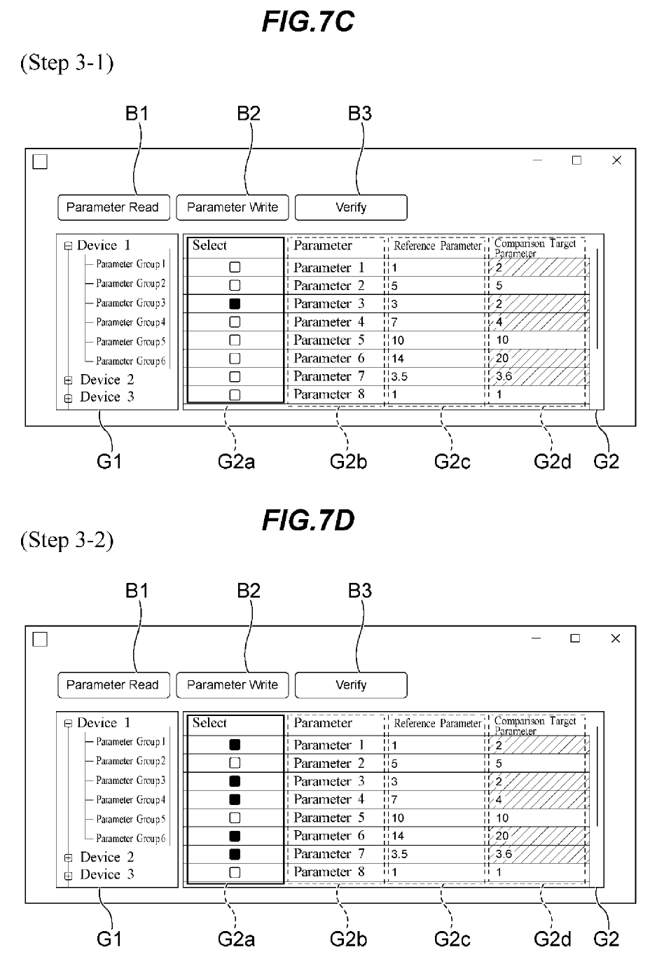

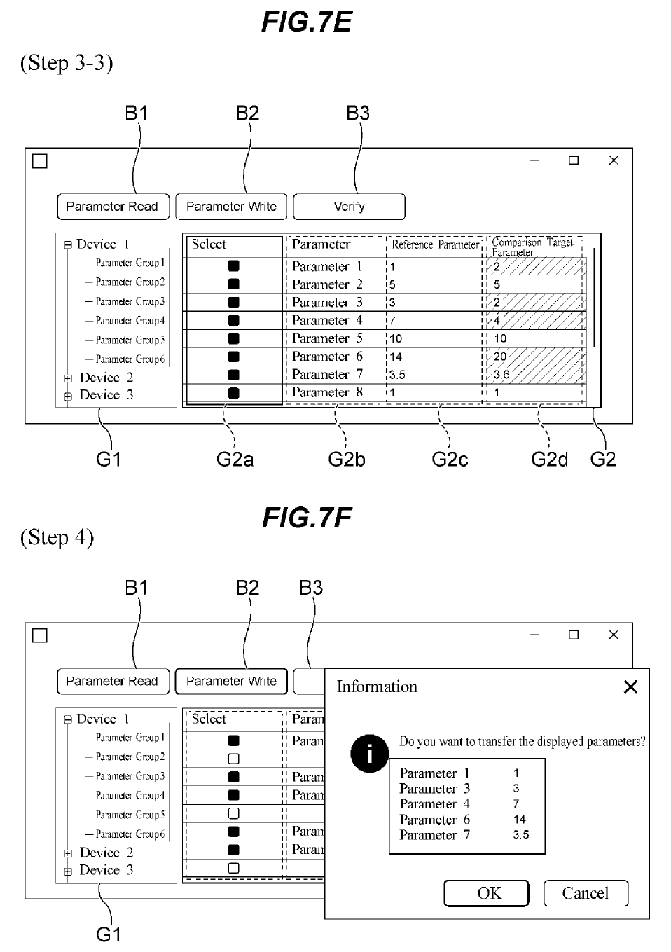

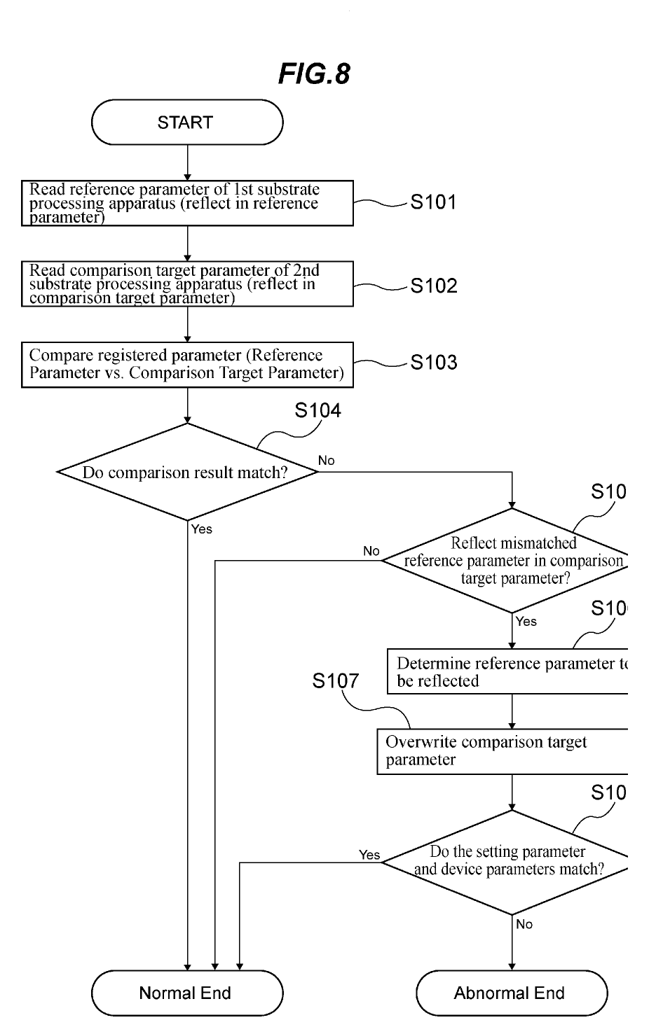

FIGS. 7A to 7F are diagrams showing an operation flow of an operation screen when reflecting the reference parameter to the target parameter. FIG. 8 is a diagram showing a processing flow of a control device when reflecting a reference parameter to a target parameter. In the embodiment shown in FIG. 8, a processing flow when transmitting and receiving parameters between a plurality of substrate processing apparatuses will be described.

As shown in Step 1 of FIG. 7A and Step S101 of FIG. 8, the control device 5 automatically reads a reference parameter of the reference device in a predetermined substrate processing apparatus SPA (first substrate processing apparatus SPA), and displays the reference parameter in the reference parameter display image G2c. Note that the device of the substrate processing apparatus SPA (and module ML) corresponding to the reference device is set in advance.

As shown in Step 2 of FIG. 7B and Step S102 of FIG. 8, when an operator selects the read button B1, the control device 5 reads a target parameter of a target device in a substrate processing apparatus SPA (second substrate processing apparatus SPA) different from the first substrate processing apparatus SPA, and displays the target parameter in the target parameter display image G2d. Note that the device of the substrate processing apparatus SPA (and module ML) corresponding to the target device is set in advance.

In the embodiment shown in FIG. 8, the reference parameter displayed in the reference parameter display image G2c is a setting parameter, but the reference parameter may be a device parameter. The target parameter displayed in the target parameter display image G2d is a setting parameter, but the target parameter may be a device parameter.

As shown in Step S103 and Step S104 of FIG. 8, the control device 5 compares the reference parameter and the target parameter, and determines whether or not a matching result between the reference parameter and the target parameter is consistent. If the matching result is completely consistent, that is, if all reference parameters and target parameters match (see "YES" in Step S104), the control device 5 ends the processing flow.

If the matching result is not consistent, that is, if at least one of the reference parameter and the target parameter does not match (see "NO" in Step S104), the control device 5 determines whether or not to reflect a mismatched reference parameter to the target parameter (see Step S105).

At this time, the control device 5 may visualize target parameters that differ from the reference parameters (see the hatched portion in Step 2 of FIG. 7B). When reflecting the mismatched reference parameter to the target parameter (see "YES" in Step S105), the operator arbitrarily selects a reference parameter to be reflected from a plurality of selection items (for example, check boxes) displayed in the selection image G2a (for example, places a check mark in a check box) (see Step 3-1 of FIG. 7C).

The operator may select only selection items corresponding to the mismatched reference parameters (see Step 3-2 of FIG. 7D), or may select all selection items (see Step 3-3 of FIG. 7E).

As shown in FIG. 6, the operation screen has a write button B2 for reflecting a selected reference parameter to a target parameter corresponding to the reference parameter. After the operator selects the reference parameter to be reflected, when the operator selects the write button B2, the control device 5 displays a pop-up screen for confirming the reference parameter to be reflected (see Step 4 of FIG. 7F). When the operator determines on the pop-up screen that the reference parameter to be reflected is correct, the control device 5 determines the reference parameter to be reflected (see Step S106).

After Step S106, the control device 5 rewrites the target parameter so that the target parameter matches the reference parameter (see Step S107). When the control device 5 determines a setting parameter of a target device as a target parameter, the control device 5 transfers the reference parameter through the communication network CN to the control device 5 as a high-order controller of the target device, and rewrites the setting parameter of the control device 5.

Thereafter, the control device 5 as the high-order controller of the target device may transfer the reference parameter to the target device through the fieldbus FB and rewrite the device parameter of the target device.

On the other hand, when the control device 5 determines a device parameter of a target device as a target parameter, the control device 5 transfers the reference parameter to the target device through the communication network CN and the fieldbus FB, and rewrites the device parameter of the target device.

When not reflecting the mismatched reference parameter to the target parameter (see "NO" in Step S105), the control device 5 ends the processing flow.

As shown in Step S108, after reflecting the reference parameter to the target parameter, that is, after causing the target parameter to match the reference parameter, the control device 5 may confirm whether or not the target parameter matches the reference parameter.

If the reference parameter and the target parameter match (see "YES" in Step S108), the control device 5 ends the processing flow. If the reference parameter and the target parameter do not match (see "NO" in Step S108), the control device 5 determines that an abnormality has occurred. In this case, the control device 5 may issue an alarm.

According to the present embodiment, the substrate processing system can transmit and receive parameters (that is, setting parameters and/or device parameters) between a plurality of control devices 5 through the communication network CN. With such a configuration, the control device 5 can centrally manage a plurality of parameters in a plurality of substrate processing apparatuses SPA, and can reflect an arbitrary reference parameter to an arbitrary target parameter. As a result, the operator does not need to manually set parameters. Therefore, the substrate processing system can reliably set parameters without causing setting errors.

In particular, the substrate processing system can easily refer to a plurality of parameters in a plurality of substrate processing apparatuses SPA and transfer parameters from one to another. Therefore, it is possible to collectively rewrite device parameters of a newly introduced substrate processing apparatus, or to easily confirm whether or not performance differences between a plurality of substrate processing apparatuses are caused by differences in device parameter settings.

In the above-described embodiment, an embodiment in which parameters are transmitted and received between a plurality of control devices 5 in a plurality of substrate processing apparatuses SPA has been described, but in an embodiment shown below, an embodiment in which parameters are transmitted and received between a data management device MD and a control device 5 in one substrate processing apparatus SPA will be described.

As shown in FIG. 1, the data management device MD is electrically connected to the control device 5 through the communication network CN, and can transmit and receive parameters with the control device 5. When the data management device MD is connected to a plurality of substrate processing apparatuses SPA, the data management device MD is configured to save (backup) data (particularly, parameters) for each substrate processing apparatus SPA.

Therefore, the data management device MD individually manages a plurality of parameters in a plurality of substrate processing apparatuses SPA in a changeable manner. The operator can confirm each parameter of a plurality of substrate processing apparatuses SPA by accessing the data management device MD.

The data management device MD comprises a database similar to the setting parameter storage database in the control device 5. Accordingly, the data management device MD stores a history (data) of past parameters for each of a plurality of substrate processing apparatuses SPA. The data management device MD may store a setting parameter definition file.

Even if a new substrate processing apparatus SPA is introduced, by connecting the new substrate processing apparatus SPA and the data management device MD with the communication network CN, the data management device MD can reflect parameters of a device DV in an already introduced substrate processing apparatus SPA to parameters of a device DV in the new substrate processing apparatus SPA. As a result, it is possible to shorten start-up work of a new substrate processing apparatus SPA without causing setting errors.

By connecting the data management device MD and the substrate processing apparatus SPA with the communication network CN, even if a plurality of substrate processing apparatuses SPA are not connected to each other by a communication network CN, the substrate processing system can realize data sharing among a plurality of substrate processing apparatuses SPA.

The data management device MD has a monitor for displaying the same operation screen as the operation screen shown in FIG. 6. Accordingly, the data management device MD displays, by the operator's operation (selection of the read button B1), setting parameters input to the control device 5 in one substrate processing apparatus SPA and device parameters stored in the device DV connected to the control device 5 by a fieldbus FB on the operation screen.

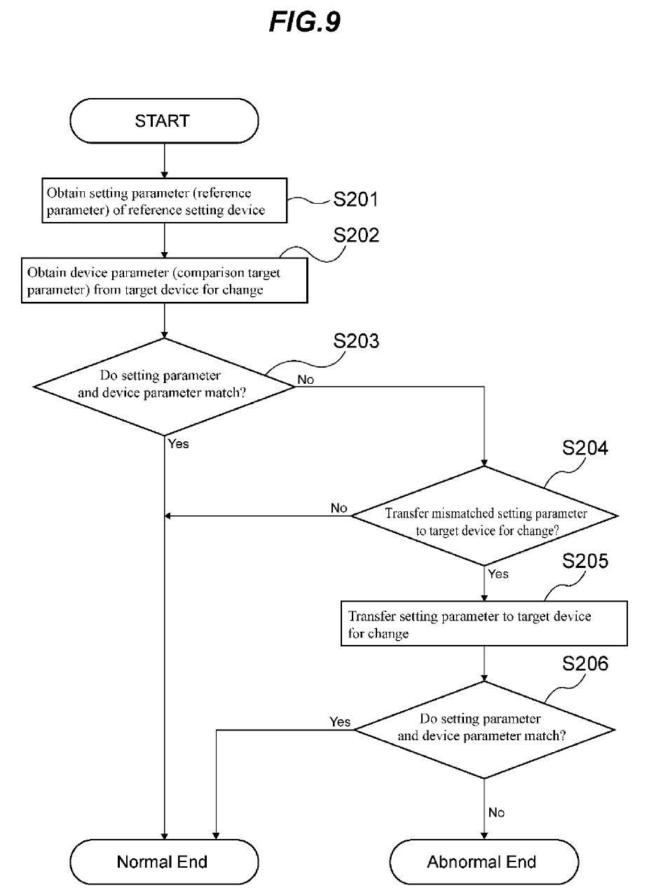

FIG. 9 is a diagram showing a processing flow of a control device when reflecting setting parameters to device parameters in one substrate processing apparatus. As shown in Step S201 of FIG. 9, the data management device MD acquires (obtains) a setting parameter of the reference device stored therein and displays the setting parameter in the reference parameter display image G2c.

As shown in Step S202, the data management device MD acquires a device parameter from a target device by an operator's operation (selection of the read button B1), and displays the device parameter in the target parameter display image G2d.

After Step S202, when the operator selects the compare button B3, the data management device MD compares the setting parameter (reference parameter) displayed in the reference parameter display image G2c and the device parameter (target parameter) displayed in the target parameter display image G2d, and determines whether or not a matching result between the setting parameter and the device parameter is consistent (see Step S203). If the matching result is completely consistent (see "YES" in Step S203), the data management device MD ends the processing flow.

If the matching result is not consistent (see "NO" in Step S203), the data management device MD determines whether or not to transfer mismatched setting parameters to the target device (see Step S204). More specifically, when at least one setting parameter and at least one device parameter do not match, the data management device MD determines whether or not to reflect the mismatched setting parameter to the device parameter.

When transferring the mismatched setting parameter to the target device (see "YES" in Step S204), the operator selects a setting parameter to be reflected (see selection image G2a in FIG. 6) and selects the write button B2. At this time, the data management device MD displays a pop-up screen for confirming the setting parameter to be transferred.

As shown in Step S205, after determining the setting parameter to be transferred, the data management device MD transfers the setting parameter to the target device through the fieldbus FB. By transferring the setting parameter, the device parameter matches the setting parameter. When not transferring the mismatched setting parameter to the device DV (see "NO" in Step S204), the data management device MD ends the processing flow.

As shown in Step S206, after causing the device parameter to match the setting parameter, the data management device MD may confirm whether or not the device parameter matches the setting parameter. If the setting parameter and the device parameter match (see "YES" in Step S206), the data management device MD ends the processing flow. If the setting parameter and the device parameter do not match (see "NO" in Step S206), the data management device MD determines that an abnormality has occurred. In this case, the data management device MD may stop processing of the wafer W and issue an alarm.

The data management device MD can centrally manage each parameter of the substrate processing apparatus SPA independently of the substrate processing apparatus SPA. Therefore, even when replacing the device DV, the data management device MD can transfer setting parameters corresponding to the former device DV to be replaced to a new device DV.

If setting parameters are manually input by the operator when inputting setting parameters corresponding to a former device DV to a new device DV after replacing the device DV, there is a risk of causing setting errors.

In the present embodiment, the data management device MD stores a history (data) of past parameters. Accordingly, the data management device MD can acquire setting parameters of a former device DV stored from the database and write the setting parameters to a new device DV. By this writing, the data management device MD can reliably transfer setting parameters to a new device DV without causing setting errors.

Further, in the present embodiment, by connecting one substrate processing apparatus SPA to the data management device MD, the data management device MD has a function as a backup for the control device 5. By connecting a plurality of substrate processing apparatuses SPA to the data management device MD, the data management device MD has a backup function for each control device 5 and can easily perform parameter management and parameter rewriting among a plurality of substrate processing apparatuses SPA.

EtherCAT communication as the fieldbus FB can execute SDO (Service Data Object) communication as an internal protocol. Accordingly, the control device 5 (and/or data management device MD) may acquire and manage firmware information of a connected device DV using SDO communication. Firmware information is, for example, a program for controlling an operation of the device DV.

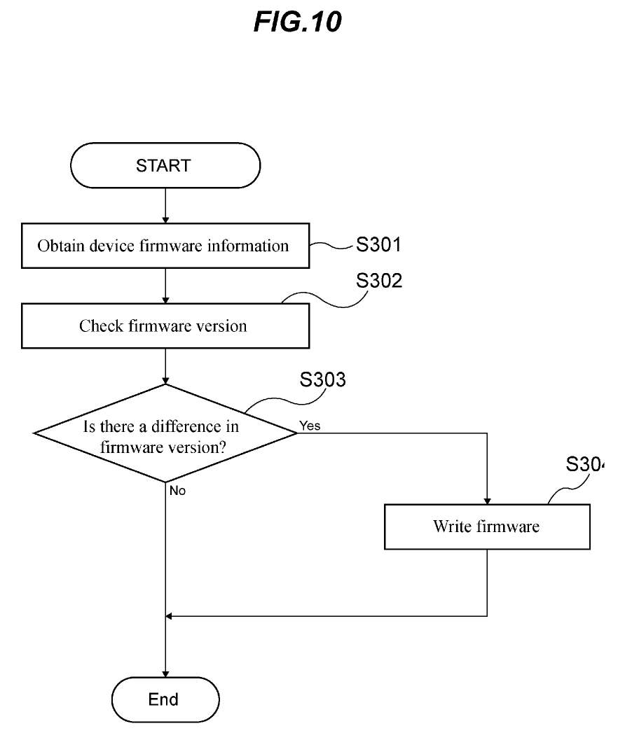

FIG. 10 is a diagram showing a processing flow of a control device for managing firmware information. As shown in Step S301 of FIG. 10, first, the control device 5 acquires firmware information of the target device DV, and confirms a current firmware version and a latest firmware version (see Step S302).

Thereafter, the control device 5 compares the current firmware version and the latest firmware version (see Step S303), and confirms whether or not there is a difference between the current firmware version and the latest firmware version, in other words, whether or not the current firmware version is the latest firmware version.

If the current firmware version is the latest (see "NO" in Step S303), the control device 5 ends the processing flow. If the current firmware version is not the latest (see "YES" in Step S303), the latest firmware version is acquired and the latest firmware is written to the device DV. In this way, the control device 5 updates the firmware version of the device DV to the latest firmware version (see Step S304).

In the embodiment described with reference to FIGS. 1 to 10, the substrate processing system comprises a plurality of substrate processing apparatuses SPA and a data management device MD connected to each of the plurality of substrate processing apparatuses SPA. With such a configuration, even if an abnormality occurs in a communication network CN connecting a plurality of substrate processing apparatuses SPA to each other, the plurality of substrate processing apparatuses SPA can communicate with each other through the data management device MD.

Further, by connecting one (or a plurality of) substrate processing apparatus SPA to the data management device MD, the data management device MD has a function as a backup for the control device 5 and can easily perform parameter management and parameter rewriting among a plurality of substrate processing apparatuses SPA.

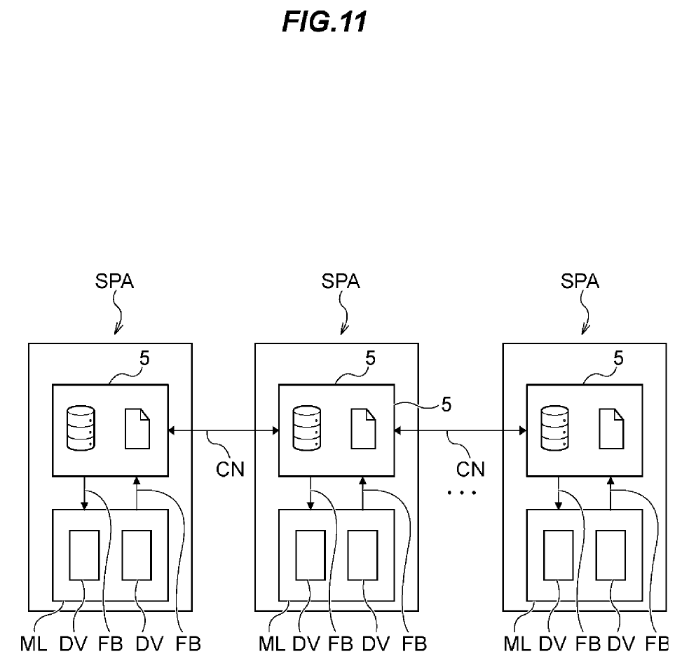

FIG. 11 is a diagram showing another embodiment of a substrate processing system. As shown in FIG. 11, the substrate processing system comprises a plurality of substrate processing apparatuses SPA while not comprising a data management device MD. The plurality of substrate processing apparatuses SPA are connected by a communication network CN. Even with such a configuration, the control device 5 in each substrate processing apparatus SPA can centrally manage parameters introduced into all substrate processing apparatuses SPA connected by the communication network CN and transfer parameters to the device DV.

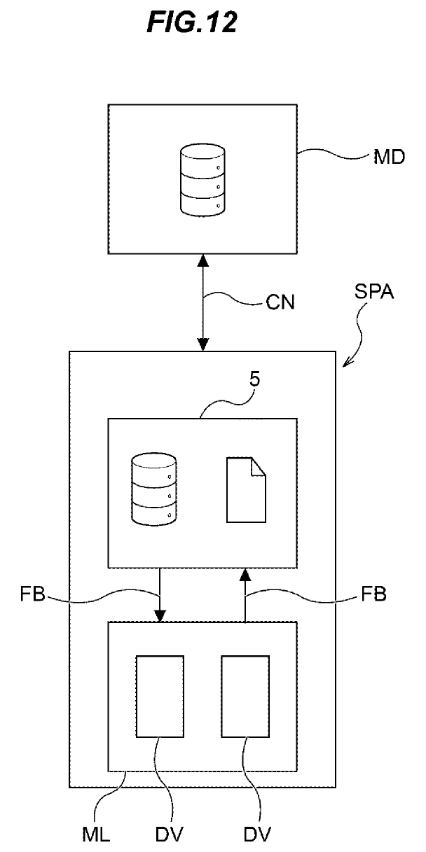

FIG. 12 is a diagram showing another embodiment of a substrate processing system. As shown in FIG. 12, the substrate processing system comprises one substrate processing apparatus SPA, the data management device MD connected to the substrate processing apparatus SPA, and the communication network CN connecting the substrate processing apparatus SPA and the data management device MD. Even with such a configuration, the data management device MD can centrally manage parameters (including not only current parameters but also past parameters) introduced into the substrate processing apparatus SPA and transfer parameters to the device DV.

The substrate processing apparatus SPA may be various substrate processing apparatuses such as a plating apparatus, a cleaning apparatus, and a film forming apparatus such as CVD.

The above-described embodiments have been described for the purpose of enabling a person having ordinary knowledge in the technical field to which the present invention belongs to implement the present invention. Various modifications of the above embodiments naturally occur to those skilled in the art, and the technical concept of the present invention can be applied to other embodiments. Therefore, the present invention is not limited to the described embodiments, but is to be interpreted in the widest scope according to the technical concept defined by the claims.

What is claimed is:

1. A substrate processing system comprising a plurality of substrate processing apparatuses,
wherein each of the substrate processing apparatuses comprises:
a control device;
a device configured to operate a module or detect an operation of the module; and
a fieldbus configured to electrically connect the control device and the device, and
wherein the substrate processing system comprises a communication network connected between a plurality of control devices including the control device and configured to transmit and receive parameters related to operating conditions of the device between the control devices.

2. The substrate processing system according to claim 1,
wherein when a device serving as a setting reference for the parameter among a plurality of devices including the device is defined as a setting reference device, and a device subject to a setting change of the parameter is defined as a target device for change, the control device is configured to display at least one reference parameter corresponding to the setting reference device and at least one target parameter corresponding to the target device for change.

3. The substrate processing system according to claim 2,
wherein the control device is configured to:
compare the reference parameter and the target parameter; and
reflect the selected reference parameter to the target parameter in a case in which the reference parameter and the target parameter do not match.

4. The substrate processing system according to claim 3,
wherein the control device is configured to, after reflecting the selected reference parameter to the target parameter, confirm whether or not the target parameter matches the reference parameter.

5. The substrate processing system according to claim 1,
wherein the substrate processing system is configured to:
transmit and receive the parameter by Ethernet communication as the communication network; and
transmit and receive the parameter by EtherCAT communication as the fieldbus.

6. A substrate processing system comprising a substrate processing apparatus,
wherein the substrate processing apparatus comprises:
a control device;
a device configured to operate a module or detect an operation of the module; and
a fieldbus configured to electrically connect the control device and the device, and
wherein the substrate processing system comprises:
a data management device electrically connected to the control device; and
a communication network configured to transmit and receive parameters related to operating conditions of the device between the control device and the data management device, and
wherein the data management device is configured to changeable manage the parameters stored therein.

7. The substrate processing system according to claim 6,
wherein the data management device is configured to display a setting parameter for setting the operating condition of the device and a device parameter stored in the device.

8. The substrate processing system according to claim 7,
wherein the data management device is configured to:
compare the setting parameter and the device parameter; and
cause the device parameter to match the setting parameter in a case in which the setting parameter and the device parameter do not match.

9. The substrate processing system according to claim 8,
wherein the data management device is configured to, after causing the device parameter to match the setting parameter, confirm whether or not the device parameter matches the setting parameter.

10. The substrate processing system according to claim 6,
wherein when replacing the device, the data management device is configured to transfer the parameter corresponding to the device to be replaced, which is stored therein, to a new device.

11. The substrate processing system according to claim 6, comprising a plurality of substrate processing apparatuses including the substrate processing apparatus, and
wherein the data management device is configured to individually manage a plurality of parameters related to operating conditions of the devices included in each of the plurality of substrate processing apparatuses.

12. The substrate processing system according to claim 6,
wherein the substrate processing system is configured to:
transmit and receive the parameters by Ethernet communication as the communication network; and
transmit and receive the parameters by EtherCAT communication as the fieldbus.
